(19) United States
(12) Patent Application Publication
(10) Pub. No.: US 2026/0130139 A1
(43) Pub. Date: May 7, 2026

(54) LOW TEMPERATURE SI-CONTAINING FILMS DEPOSITED FROM CHLOROSILANE AND AMINOSILANE REACTIONS

(71) Applicant: VERSUM MATERIALS US, LLC, TEMPE, AZ (US)

(72) Inventors: MATTHEW R. MACDONALD, MISSION VIEJO, CA (US); HARIPIN CHANDRA, SAN MARCOS, CA (US); RANDALL HIGUCHI, SANTA CLARA, CA (US); XINJIAN LEI, VISTA, CA (US); SON HOANG, SAN JOSE, CA (US)

(21) Appl. No.: 19/120,665

(22) PCT Filed: Oct. 12, 2023
(86) PCT No.: PCT/US2023/035020

§ 371 Date: Apr. 11, 2025

Related U.S. Application Data
(60) Provisional application No. 63/379,433, filed on Oct. 13, 2022.

(51) Int. Cl. H10P 14/60; C23C 16/34; C23C 16/44; C23C 16/455; H01J 37/32; H10P 14/694

(52) U.S. Cl. CPC H10P 14/6339; C23C 16/345; C23C 16/4408; C23C 16/45527; C23C 16/45553; H01J 37/32449; H10P 14/6682; H10P 14/69433; H01J 2237/338

(57) ABSTRACT

A method for deposition of silicon and nitrogen containing dielectric film via an atomic layer deposition (ALD) or in an ALD-like process. The method includes the steps of a) providing at least one substrate into a reactor and heating the reactor to at least one temperature ranging from about 25° C. to about 600° C. and optionally maintaining the reactor at a pressure of about 100 torr or less; b) introducing into the reactor at least a first precursor comprising a halogenated silicon-containing compound that forms a silicon-containing layer; c) purging any unreacted precursor from the reactor using inert gas; d) introducing at least a second precursor, comprising at least two or more primary amino-containing silicon atoms, which reacts with the silicon-containing layer to form a film comprising silicon and nitrogen; e) purging the reactor using inert gas; f) introducing a plasma source into the reactor to react with the film comprising silicon and nitrogen; g) purging any reaction by-products from the reactor using inert gas, and repeating steps b to g to bring the film comprising silicon and nitrogen to a desired thickness.

### CROSS-REFERENCE TO RELATED APPLICATIONS

This application claims the benefit of U.S. provisional patent application Ser. No. 63/379,433, filed Oct. 13, 2022.

### FIELD OF THE INVENTION

The present invention is directed to compositions and methods for the fabrication of an electronic device. More specifically, the invention is directed to compounds, compositions and methods for the deposition of a high quality dense silicon-containing film such as, without limitation, a stoichiometric silicon nitride, a carbon-doped silicon nitride film, and a carbon-doped silicon oxynitride film.

### BACKGROUND OF THE INVENTION

Silicon nitride films are used in semiconductors for a variety of applications. For example, a silicon nitride film is commonly used as a final passivation and mechanical protective layer for integrated circuits, a mask layer for selective oxidation of silicon, as one of the dielectric materials in a stacked oxide-nitride-oxide (O—N—O) layer in a DRAM capacitor or in 3D NAND flash memory chips, or as a CMP stop layer in a shallow trench isolation application. In one particular application, the O—N—O stack in a 3D NAND flash requires silicon nitride with low stress and a high wet etch rate in phosphoric acid.

Olsen, “Analysis of LPCVD Process Conditions for the Deposition of Low Stress Silicon Nitride”, 5 Materials Science in Semiconductor Process 51 (2002) describes a wide range of process conditions that are used to optimize the deposition of low stress silicon nitride films by low-pressure chemical vapor deposition. The results show that an increase in the index of refraction beyond 2.3 by means of increasing the gas flow did not reduce the residual stress appreciably but had a significant detrimental effect on the thickness uniformity and deposition rate.

M. Tanaka et al., “Film Properties of Low-k Silicon Nitride Films Formed by Hexachlorodisilane and Ammonia”, 147 J. Electrochem. Soc. 2284 (2000) describes a low-temperature process with good step coverage of silicon nitride (SiN) formed by low-pressure chemical vapor deposition (LPCVD) using hexachlorodisilane (HCD).

JP2000100812 describes a method for depositing a film using SiCl₄ and NH₃ as source gases. The substrate surface may be nitrided using NH₃ prior to deposition. An extremely thin film having an improved insulator property is formed. The silicon nitride film is useful as a capacitor insulator film of a semiconductor integrated circuit.

U.S. Pat. No. 6,355,582 describes a method for forming a silicon nitride film wherein the substrate to be subjected to the film formation is heated, and silicon tetrachloride and ammonia gases are supplied to the substrate heated to a predetermined temperature.

U.S. Pat. No. 10,049,882 describes an atomic layer deposition (ALD) method for fabricating a semiconductor device including the step of forming a dielectric layer on a structure having a height difference. The method includes forming a structure with a height difference on a substrate and forming a dielectric layer structure on the structure. Forming the dielectric layer structure includes forming a first dielectric layer including silicon nitride on the structure with the height difference. Forming the first dielectric layer includes feeding a first gas including pentachlorodisilane (PCDS) or diisopropylamine pentachlorodisilane (DPDC) as a silicon precursor, and a second gas including nitrogen components into a chamber including the substrate such that the first dielectric layer is formed in situ on the structure having the height difference.

PCT Pub. No. WO2018063907 discloses a class of chlorodisilazanes, silicon-heteroatom compounds synthesized therefrom, devices containing the silicon-heteroatom compounds, methods of making the chlorodisilazanes, the silicon-heteroatom compounds, and the devices; and uses of the chlorodisilazanes, silicon-heteroatom compounds, and devices.

PCT Pub. No. WO2018057677 discloses a composition that includes trichlorodisilane as a silicon precursor for use in film forming. The composition includes the silicon precursor compound and at least one of an inert gas, molecular hydrogen, a carbon precursor, a nitrogen precursor, and an oxygen precursor. The publication also discloses a method of forming a silicon-containing. film on a substrate using the silicon precursor compound and the silicon-containing film formed thereby.

U.S. Pat. No. 9,984,868 discloses cyclical methods of depositing a silicon nitride film on a substrate. In one embodiment such a method includes supplying a halogen silane as a silicon precursor into a reactor; supplying a purge gas to the reactor; and providing an ionized nitrogen precursor into the reactor to react with the substrate and form the silicon nitride film.

US Pub. No. 2009/0155606 discloses cyclical methods of depositing a silicon nitride film on a substrate. In one embodiment a method includes supplying a chlorosilane to a reactor in which a substrate is processed; supplying a purge gas to the reactor; and providing ammonia plasma to the reactor. The method allows a silicon nitride film to be formed at a low process temperature and a high deposition rate. The resulting silicon nitride film has relatively few impurities and a relatively high quality. In addition, a silicon nitride film having good step coverage over features having high aspect ratios and a thin and uniform thickness can be formed.

Finally, U.S. Pat. No. 9,018,104 discloses a method for manufacturing a semiconductor device, including forming an insulating film having a prescribed composition and a prescribed film thickness on a substrate by alternately performing the following steps prescribed number of times: supplying one of the sources of a chlorosilane-based source and an aminosilane-based source to a substrate in a processing chamber, and thereafter supplying the other source, to form a first layer containing silicon, nitrogen, and carbon on the substrate; and supplying a reactive gas different from each of the sources, to the substrate in the processing chamber, to modify the first layer and form a second layer.

The disclosures of the previously identified patents, patent applications and publications are hereby incorporated by reference.

There is a need in the art to provide a method for depositing silicon nitride or carbon-doped silicon nitride at temperatures 600° C. or lower, preferably 500° C. or lower, most preferably 400° C. or lower having the following characteristic: a carbon content of about 5 atomic % or less, about 3 atomic % or less, about 2 atomic % or less, about 1 atomic % or even less as measured by X-ray photoelectron spectroscopy (XPS), preferably stoichiometric silicon nitride; an oxygen content of about 5 atomic % or less, about 3 atomic % or less, about 2 atomic % or less, about 1 atomic % or less as measured by X-ray photoelectron spectroscopy (XPS); a step coverage of 90% or higher, 95% or higher, 99% or higher, and a dielectric constant of 7.0 or less, 6.0 or less, or 5.0 or less.

### BRIEF SUMMARY OF THE INVENTION

The above-described needs are met in one respect by providing a method for deposition of silicon and nitrogen containing dielectric film via an atomic layer deposition (ALD) process, comprising: a) providing at least one substrate into a reactor at a temperature ranging from about 25° C. to about 600° C. and optionally maintaining the reactor at a pressure of about 100 torr or less; b) introducing into the reactor at least a first silicon precursor comprising at least two halogen atoms to form a silicon-containing layer; c) purging any unreacted precursor from the reactor using inert gas; d) introducing into the reactor at least a second silicon precursor, comprising at least two primary amino moieties, which reacts with the silicon-containing layer to form a film comprising silicon and nitrogen; e) purging the reactor using inert gas; f) introducing a plasma source into the reactor to react with the film comprising silicon and nitrogen: g) purging any reaction by-products from the reactor using inert gas, and h) repeating steps b to g to bring the film comprising silicon and nitrogen to a desired thickness.

The above-described needs are further met in one respect by providing a method for deposition of silicon and nitrogen containing dielectric film via an atomic layer deposition (ALD) process, comprising: a) providing at least one substrate into a reactor at a temperature ranging from about 25° C. to about 600° C. and optionally maintaining the reactor at a pressure of about 100 torr or less; b) introducing at least a first silicon precursor comprising at least two primary amino moieties to form a film comprising a silicon containing layer; c) purging any unreacted precursor from the reactor using inert gas; d) introducing into the reactor at least a second silicon precursor comprising at least two halogen atoms to react with the silicon containing layer to form a film comprising silicon and nitrogen; e) purging the reactor using inert gas; f) introducing a plasma source into the reactor to react with the film comprising silicon and nitrogen; g) purging any reaction by-products from the reactor using inert gas, and h) repeating steps b to g to bring the film comprising silicon and nitrogen to a desired thickness.

### DETAILED DESCRIPTION OF THE INVENTION

Throughout the description, the term “ALD or ALD-like” refers to a process including, but not limited to, the following processes: a) each reactant including silicon precursor and reactive gas is introduced sequentially into a reactor such as a single wafer ALD reactor, semi-batch ALD reactor, or batch furnace ALD reactor; b) each reactant including silicon precursor and reactive gas is exposed to a substrate by moving or rotating the substrate to different sections of the reactor and each section is separated by inert gas curtain, i.e. spatial ALD reactor or roll to roll ALD reactor.

Throughout the description, the term “plasma including/comprising ammonia” refers to a reactive gas or gas mixture generated in situ or remotely via a plasma generator. The gas or gas mixture is selected from the group consisting of ammonia, a mixture of ammonia and helium, a mixture of ammonia and neon, a mixture of ammonia and argon, a mixture of ammonia and nitrogen, a mixture of ammonia and hydrogen, and combinations thereof.

Throughout the description, the term “plasma including/comprising hydrogen or deuterium” refers to a reactive gas or gas mixture generated in situ or remotely via a plasma generator. The gas or gas mixture is selected from the group consisting of hydrogen or deuterium, a mixture of hydrogen or deuterium and helium, a mixture of hydrogen or deuterium and neon, a mixture of hydrogen and argon, a mixture of hydrogen or deuterium and nitrogen and combinations thereof. Throughout the description, the term “alkyl” refers a linear or branched C₁ to C₂₀ hydrocarbon, cyclic C₆ to C₂₀ hydrocarbon. Exemplary hydrocarbons include, but are not limited to, heptane, octane, nonane, decane, dodecane, cyclooctane, cyclononane, and cyclodecane.

Throughout the description, the term “step coverage” as used herein is defined as a percentage of two thicknesses of the deposited film in a structured or featured substrate having either vias or trenches or both. Bottom step coverage is defined as the ratio (in of the thickness at the bottom of the feature divided by thickness at the top of the feature. Middle step coverage is defined as the ratio (in %) of the thickness on a sidewall of the feature divided by thickness at the top of the feature. Films deposited using the method described herein exhibit a step coverage of about 80% or greater, or about 90% or greater which indicates that the films are conformal.

Throughout the description, the term “silicon precursor” as used herein is defined as either a halogenated silicon-containing compound comprising at least two halogen atoms or a primary amino-containing silicon compound comprising at least two primary amino moieties.

Throughout the description, the term “primary amino-containing” as used herein is defined as an organoamino group or moiety HNR¹ derived by removal one hydrogen from a primary organoamine H₂NR¹. Exemplary primary amino-containing groups include, but are not limited to, ethylamino (—NHEt), n-propylamino (—NHPrⁿ), and iso-propylamino (—NHPrⁱ).

It is believed that reaction between the hydrogen of Si—NH and Si—Cl via sequentially introducing a halogenated silicon-containing compound, and a precursor comprising at least two or more primary amino-containing silicon compound followed by either ammonia containing plasma or hydrogen containing plasma. The new process can potentially create more Si—N—Si network wherein the nitrogen atom is bonded to three silicon atoms, thus allowing formation of better silicon nitride films. The existing prior art typically involves one silicon precursor followed by plasma, for example, a halogenated silicon-containing compound followed by nitrogen or ammonia containing plasma. Importantly, the key invention of the patent is to deposit silicon nitride with more nitrogen atoms bonded to three silicon atoms at low temperature, thus providing a silicon nitride film having low hydrogen content with lower wet etch rates than existing art employing only one silicon precursor.

Described herein is a method for deposition of silicon and nitrogen containing dielectric film via an atomic layer deposition (ALD) or in an ALD-like process such as, without limitation, a cyclic chemical vapor deposition process (CCVD).

In one embodiment, the method described according to an exemplary embodiment comprises
a) providing at least one substrate into a reactor at a temperature ranging from about 25° C. to about 600° C. and optionally maintaining the reactor at a pressure of about 100 torr or less;
b) introducing into the reactor at least a first silicon precursor comprising at least two halogen atoms to form a silicon-containing layer;
c) purging any unreacted precursor from the reactor using inert gas;
d) introducing into the reactor at least a second silicon precursor, comprising at least two primary amino moieties, which reacts with the silicon-containing layer to form a film comprising silicon and nitrogen;
e) purging the reactor using inert gas;
f) introducing a plasma source into the reactor to react with the film comprising silicon and nitrogen; and
g) purging any reaction by-products from the reactor using inert gas.
   Steps b to g in this embodiment may be repeated to provide a desired thickness of silicon and nitrogen containing dielectric.

In some embodiments of this invention, steps d to e can be performed before steps b and c. The thickness of silicon and nitrogen containing dielectric films ranges from 1 Å to 1000 Å, or 1 Å to 500 Å, or 1 Å to 300 Å, or 1 Å to 200 Å, or 1 Å to 100 Å, or 1 Å to 50 Å. The thickness of the silicon nitride or silicon carbonitride films may also range from 5 Å to 500 Å, or 5 Å to 400 Å, or 5 Å to 300 Å, or 5 Å to 200 Å, or 5 Å to 100 Å, or 5 Å to 50 Å.

In another embodiment, the method described according to an exemplary embodiment comprises:
a) providing at least one substrate into a reactor at a temperature ranging from about 25° C. to about 600° C. and optionally maintaining the reactor at a pressure of about 100 torr or less;
b) introducing at least a first silicon precursor comprising at least two primaryamino moieties to form a film comprising a silicon containing layer;
c) purging any unreacted precursor from the reactor using inert gas;
d) introducing into the reactor at least a second silicon precursor comprising at least two halogen atoms to react with the silicon containing layer to form a film comprising silicon and nitrogen;
e) purging the reactor using inert gas;
f) introducing a plasma source into the reactor to react with the film comprising silicon and nitrogen; and
g) purging any reaction by-products from the reactor using inert gas.
   Steps b to i in this embodiment may be repeated to provide a desired thickness of silicon and nitrogen containing dielectric.

In some embodiments of this invention, steps d to e can be performed before steps b and c. The thickness of silicon and nitrogen containing dielectric films ranges from 1 Å to 1000 Å, or 1 Å to 500 Å, or 1 Å to 300 Å, or 1 Å to 200 Å, or 1 Å to 100 Å, or 1 Å to 50 Å. The thickness of the silicon nitride or silicon carbonitride films may also range from 5 Å to 500 Å, or 5 Å to 400 Å, or 5 Å to 300 Å, or 5 Å to 200 Å, or 5 Å to 100 Å, or 5 Å to 50 Å.

In yet other embodiment, the method described according to an exemplary embodiment comprises:
a) providing at least one substrate and heating the reactor to at least one temperature ranging from about 25° C. to about 600° C. and optionally maintaining the reactor at a pressure of about 100 torr or less;
b) introducing into the reactor at least a first precursor comprising a halogenated silicon-containing compound that forms a silicon-containing layer;
c) purging any unreacted precursor from the reactor using inert gas;
d) introducing at least a second precursor comprising one at least two or more primary amino-containing silicon compound that reacts with the silicon-containing layer to form a film comprising silicon and nitrogen;
e) purging the reactor using inert gas;
f) introducing ammonia containing plasma source into the reactor to react with the film comprising silicon and nitrogen;
g) purging any reaction by-products from the reactor using inert gas.

Steps b to g in this embodiment may be repeated to provide a desired thickness of silicon and nitrogen containing dielectric. In some embodiments of this invention, steps d to e can be performed before steps b and c. The thickness of silicon and nitrogen containing dielectric films ranges from 1 Å to 1000 Å, or 1 Å to 500 Å, or 1 Å to 300 Å, or 1 Å to 200 Å, or 1 Å to 100 Å, or 1 Å to 50 Å. The thickness of the silicon nitride or silicon carbonitride films may also range from 5 Å to 500 Å, or 5 Å to 400 Å, or 5 Å to 300 Å, or 5 Å to 200 Å, or 5 Å to 100 Å, or 5 Å to 50 Å.

Further, in another embodiment, the method described according to an exemplary embodiment comprises:
a) providing at least one substrate and heating the reactor to at least one temperature ranging from about 25° C. to about 600° C. and optionally maintaining the reactor at a pressure of about 100 torr or less;
b) introducing into the reactor at least a first precursor comprising a halogenated silicon-containing compound that forms a silicon-containing layer;
c) purging any unreacted precursor from the reactor using inert gas;
d) introducing at least a second precursor comprising one at least two or more primary amino-containing silicon compound that reacts with the silicon-containing layer to form a film comprising silicon and nitrogen;
e) purging the reactor using inert gas;
f) introducing a non-nitrogen comprising plasma source into the reactor to react with the film comprising silicon and nitrogen;
g) purging the reactor using inert gas.

Steps b to g in this embodiment may be repeated to provide a desired thickness of silicon and nitrogen containing dielectric. In some embodiments of this invention, steps d to e can be performed before steps b and c. The thickness of silicon and nitrogen containing dielectric films ranges from 1 Å to 1000 Å, or 1 Å to 500 Å, or 1 Å to 300 Å, or 1 Å to 200 Å, or 1 Å to 100 Å, or 1 Å to 50 Å. The thickness of the silicon nitride or silicon carbonitride films may also range from 5 Å to 500 Å, or 5 Å to 400 Å, or 5 Å to 300 Å, or 5 Å to 200 Å, or 5 Å to 100 Å, or 5 Å to 50 Å.

Exemplary halogenated silicon-containing compounds can be selected from the group consisting of: i) halogenated silanes, ii) halogenated siloxanes, iii) halogenated silazanes, and iv) halogenated carbosilanes.

The halogenated silanes of group i include, but are not limited to, trichlorosilane, tetrachlorosilane, hexachlorodisilane, pentachlorodisilane, tetrachlorodisilane, octachlorotrisilane, and dichlorosilane.

The halogenated siloxanes of group ii include, but are not limited to, hexachlorodisiloxane, pentachlorodisiloxane, tetrachlorodisiloxane, and octaclorotrisiloxane.

The halogenated silazanes of group iii are selected from the groups represented by the following Formula I below:

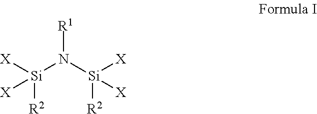

wherein R¹ is selected from the group consisting of hydrogen, a linear or branched C₁ to C₁₀ alkyl group, a linear or branched C₂ to C₁₀ alkenyl group, a linear or branched C₂ to C₁₀ alkynyl group, a C₃ to C₁₀ cyclic alkyl group, a C₂ to C₆ dialkylamino group, an electron withdrawing group, and a C₆ to C₁₀ aryl group; R² is selected from the group consisting of hydrogen, a linear or branched C₁ to C₁₀ alkyl group, a linear or branched C₂ to C₆ alkenyl group, a linear or branched C₂ to C₆ alkynyl group, a C₃ to C₁₀ cyclic alkyl group, a C₂ to C₆ dialkylamino group, a C₆ to C₁₀ aryl group, a linear or branched C₁ to C₆ fluorinated alkyl group, an electron withdrawing group, and a halide selected from the group consisting of Cl, Br, and I; and X is a halide selected from the group consisting of Cl, Br, and I.

Examples of group iii of halogenated silazanes may be selected from the group consisting of 1,1,1,3,3,3-hexachloro-disilazane, 1,1,1,3,3-pentachloro-disilazane, 1,1,1,3,3,3-hexachloro-2-methyldisilazane, 1,1,1,3,3,3-hexachloro-2-ethyldisilazane, 1,1,1,3,3,3-hexachloro-2-n-propyldisilazane, 1,1,1,3,3,3-hexachloro-2-iso-propyldisilazane, 1,1,1,3,3,3-hexachloro-2-n-butyldisilazane, 1,1,1,3,3,3-hexachloro-2-iso-butyldisilazane, 1,1,1,3,3,3-hexachloro-2-sec-butyldisilazane, 1,1,1,3,3,3-hexachloro-2-tert-butyldisilazane, 1,1,1,3,3,3-hexabromo-2-methyldisilazane, 1,1,1,3,3,3-hexabromo-2-ethyldisilazane, 1,1,1,3,3,3-hexabromo-2-n-propyldisilazane, 1,1,1,3,3,3-hexabromo-2-iso-propyldisilazane, 1,1,1,3,3,3-hexabromo-2-n-butyldisilazane, 1,1,1,3,3,3-hexabromo-2-iso-butyldisilazane, 1,1,1,3,3,3-hexabromo-2-sec-butyldisilazane, 1,1,1,3,3,3-hexabromo-2-tert-butyldisilazane, 1,1,1,3,3,3-hexaiodo-2-methyldisilazane, 1,1,1,3,3,3-hexaiodo-2-ethyldisilazane, 1,1,1,3,3,3-hexaiodo-2-n-propyldisilazane, 1,1,1,3,3,3-hexaiodo-2-iso-propyldisilazane, 1,1,1,3,3,3-hexaiodo-2-n-butyldisilazane, 1,1,1,3,3,3-hexaiodo-2-iso-butyldisilazane, 1,1,1,3,3,3-hexaiodo-2-sec-butyl-disilazane, 1,1,1,3,3,3-hexaiodo-2-tert-butyl-disilazane, 1,1,1,3,3-pentachloro-2-methyldisilazane, 1,1,1,3,3-pentachloro-2-ethyldisilazane, 1,1,1,3,3-pentachloro-2-n-propyldisilazane, 1,1,1,3,3-pentachloro-2-iso-propyldisilazane, 1,1,1,3,3-pentachloro-2-methyl-3-methyldisilazane, 1,1,1,3,3-pentachloro-2-ethyl-3-methyldisilazane, 1,1,1,3,3-pentachloro-2-n-propyl-3-methyldisilazane, 1,1,1,3,3-pentachloro-2-iso-propyl-3-methyldisilazane, 1,1,3,3-tetrachloro-2-methyldisilazane, 1,1,3,3-tetrachloro-2-ethyldisilazane, 1,1,3,3-tetrachloro-2-n-propyldisilazane, 1,1,3,3-tetrachloro-2-iso-propyldisilazane, 1,1,3,3-tetrachloro-2-n-butyldisilazane, 1,1,3,3-tetrachloro-2-iso-butyldisilazane, 1,1,3,3-tetrachloro-2-sec-butyldisilazane, 1,1,3,3-tetrachloro-2-tert-butyldisilazane. 1,1,3,3-tetrabromo-2-methyldisilazane, 1,1,3,3-tetrabromo-2-ethyldisilazane, 1,1,3,3-tetrabromo-2-n-propyldisilazane, 1,1,3,3-tetrabromo-2-iso-propyldisilazane, 1,1,3,3-tetrabromo-2-n-butyldisilazane, 1,1,3,3-tetrabromo-2-iso-butyldisilazane, 1,1,3,3-tetrabromo-2-sec-butyldisilazane, 1,1,3,3-tetrachloro-2-tert-butyldisilazane, 1,1,3,3-tetraiodo-2-methyldisilazane, 1,1,3,3-tetraiodo-2-ethyldisilazane, 1,1,3,3-tetraiodo-2-n-propyldisilazane, 1,1,3,3-tetraiodo-2-iso-propyldisilazane, 1,1,3,3-tetraiodo-2-n-butyldisilazane, 1,1,3,3-tetraiodo-2-iso-butyldisilazane, 1,1,3,3-tetraiodo-2-sec-butyldisilazane, 1,1,3,3-tetraiodo-2-tert-butyldisilazane, 1,1,3,3-tetrachloro-2-cyclopentyldisilazane, 1,1,3,3-tetrachloro-2-cyclohexyldisilazane, 1,1,3,3-tetrachloro-1,3-dimethyl-2-cyclopentyl-2-cyclopentyldisilazane, 1,1,3,3-tetrachloro-1,3-dimethyl-2-cyclohexyldisilazane, 1,1,3,3-tetrachloro-1,3-dimethyl-2-methyldisilazane, 1,1,3,3-tetrachloro-1,3-dimethyl-tetrachloro-2-ethyldisilazane, 1,1,3,3-tetrachloro-1,3-dimethyl-2-n-propyldisilazane, 1,1,3,3-tetrachloro-1,3-dimethyl-2-iso-propyldisilazane, 1,1,3,3-tetrachloro-1,3-dimethyl-2-n-butyldisilazane, 1,1,3,3-tetrachloro-1,3-dimethyl-2-iso-butyldisilazane, 1,1,3,3-tetrachloro-1,3-dimethyl-2-sec-butyldisilazane, and 1,1,3,3-tetrachloro-1,3-dimethyl-2-tert-butyldisilazane.

Examples of group iv halogenated carbosilanes may be selected from the group consisting of 1,1,1,4,4,4-hexachloro-1,4-disilabutane, 1,1,1,4,4,4-hexachloro-2-methyl-1,4-disilabutane, 1,1,1,4,4-pentachloro-1,4-disilapentane, 1,1,1,4,4-pentachloro-2-methyl-1,4-disilapentane, 2,2,5,5-tetrachloro-2,5-disilahexane, 2,2,5,5-tetrachloro-3-methyl-2,5-disilahexane, 1,1,1,5,5,5-hexachloro-1,5-disilapentane, 2,2,6,6-tetrachloro-3-methyl-2,6-disilaheptane, 1,1,4,4-tetrachloro-1,4-disilapentane, 1,1,4,4-tetrachloro-2-methyl-1,4-disilapentane, 1,1,4,4,4-pentachloro-1,4-disilabutane, 1,1,4,4,4-pentachloro-2-methyl-1,4-disilabutane, 1,4,4,4-tetrachloro-1,4-disilabutane, 1,4,4,4-tetrachloro-2-methyl-1,4-disilabutane, 1,4,4-trichloro-1,4-disilapentane, 1,4,4-trichloro-2-methyl-1,4-disilapentane, 1,1,5,5,5-pentachloro-1,5-disilapentane, 1,1,5,5,5-pentachloro-2-methyl-1,5-disilapentane, 1,1,5,5-tetrachloro-1,5-disilahexane, 1,1,5,5-tetrachloro-2-methyl-1,5-disilahexane, 1,5,5,5-tetrachloro-1,5-disilapentane, 1,5,5,5-tetrachloro-2-methyl-1,5-disilapentane, 1,5,5-trichloro-1,5-disilahexane, 1,5,5-trichloro-2-methyl-1,5-disilahexane, 1,3-dichloro-1,3-disilacyclobutane, 1,3-dibromo-1,3-disilacyclobutane, 1,1,3-trichloro-1,3-disilacyclobutane, 1,1,3-tribromo-1,3-disilacyclobutane, 1,1,3,3-tetrachloro-1,3-disilacyclobutane, 1,1,3,3-tetrabromo-1,3-disilacyclobutane, 1,3-dichloro-1,3-dimethyl-1,3-disilacyclobutane, 1,3-bromo-1,3-dimethyl-1,3-disilacyclobutane, 1,1,1,3,3,5,5,5-octachloro-1,3,5-trisilapentane, 1,1,1,3,3,5,5,5-octabromo-1,3,5-trisilapentane, 1,1,3,3,5,5-hexachloro-1,5-dimethyl-1,3,5-trisilapentane, 1,1,1,5,5,5-hexachloro-3,3-dimethyl-1,3,5-trisilapentane, 1,1,3,5,5-pentachloro-1,3,5-trimethyl-1,3,5-trisilapentane, 1,1,1,5,5,5-hexachloro-1,3,5-trisilapentane, 1,1,5,5-tetrachloro-1,3,5-trisilapentane, 1,1-diiodo-1,3-disilacyclobutane, 1,3-diiodo-1,3-disilacyclobutane, 1,1,3-triiodo-1,3-disilacyclobutane, 1,1,3,3-tetraiodo-1,3-disilacyclobutane, 1,3-diiodo-1,3-dimethyl-1,3-disilacyclobutane, 1,5-dichloro-1,3,5-trisilapentane, 1,5-dibromo-1,3,5-trisilapentane, and 1,5-diiodo-1,3,5-trisilapentane.

The primary amino-containing silicon compounds can be selected from the groups represented by the following Formula II below:

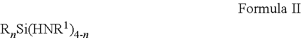

wherein R is selected from the group consisting of hydrogen, a linear or branched C₁ to C₁₀ alkyl group, a linear or branched C₂ to C₁₀ alkenyl group, a linear or branched C₂ to C₁₀ alkynyl group, a C₃ to C₁₀ cyclic alkyl group, a C₂ to C₆ dialkylamino group, an electron withdrawing group, and a C₆ to C₁₀ aryl group; R¹ is selected from the group consisting of hydrogen, a linear or branched C₁ to C₁₀ alkyl group, a linear or branched C₂ to C₆ alkenyl group, a linear or branched C₂ to C₆ alkynyl group, a C₃ to C₁₀ cyclic alkyl group, a C₂ to C₆ dialkylamino group, a C₆ to C₁₀ aryl group, a linear or branched C₁ to C₆ fluorinated alkyl group, an electron withdrawing group, and a halide selected from the group consisting of Cl, Br, and I; and n=0, 1, and 2. In a preferred embodiment, n=0, R¹ is methyl, ethyl, n-propyl; In another preferred embodiment, n=1, R is methyl, ethyl while R¹ is methyl, ethyl, n-propyl, n-butyl, i-propyl. Examples include, but not limited to Si(HNEt)₄, Si(HNPr-n)₄, Si(HNPr-i)₄, Si(HNBu-n)₄, MeSi(HNEt)₃, MeSi(HNPr-n)₃, MeSi(HNPr-i)₃, and MeSi(HNBu-n)₃.

The primary amino-containing silicon compounds can also be selected from the groups represented by the following Formula III below:

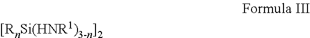

wherein R is selected from the group consisting of hydrogen, a linear or branched C₁ to C₁₀ alkyl group, a linear or branched C₃ to C₁₀ alkenyl group, a linear or branched C₃ to C₁₀ alkynyl group, a C₃ to C₁₀ cyclic alkyl group, a C₂ to C₆ dialkylamino group, an electron withdrawing group, and a C₆ to C₁₀ aryl group; R¹ is selected from the group consisting of hydrogen, a linear or branched C₁ to C₁₀ alkyl group, a linear or branched C₂ to C₆ alkenyl group, a linear or branched C₃ to C₆ alkynyl group, a C₃ to C₁₀ cyclic alkyl group, a C₂ to C₆ dialkylamino group, a C₆ to C₁₀ aryl group, a linear or branched C₁ to C₆ fluorinated alkyl group, an electron withdrawing group, and a halide selected from the group consisting of Cl, Br, and I; and n=0, 1, and 2. Examples include, but not limited to of Si₂(HNEt)₆, Me(EtNH)₂SiSi(HNEt)₂Me, Me₂(EtNH)SiSi(HNEt)Me₂, Si₂(HNMe)₆, Me(MeNH)₂SiSi(HNMe)₂Me, and Me₂(MeNH)SiSi(HNMe)Me₂.

The plasma source can be selected from the group consisting of nitrogen-containing plasma, ammonia-containing plasma, inert-gas plasma, and hydrogen-containing plasma. The nitrogen-containing source gases may include, for example, nitrogen/argon plasma, nitrogen/helium plasma. The ammonia-containing plasma may include, for example, ammonia plasma, ammonia/argon plasma, ammonia/helium plasma, ammonia/hydrogen plasma, ammonia/nitrogen plasma. The inert-gas plasma may include, for example, argon plasma, helium plasma and combination thereof. The hydrogen plasma may include, for example, hydrogen plasma, hydrogen/helium plasma, hydrogen/argon and combination thereof. A non-nitrogen comprising plasma source can be selected from the group consisting of an inert gas plasma, a hydrogen-containing plasma, and combination thereof. The inert gas is selected from the group consisting of argon (Ar), nitrogen (N₂), helium (He), neon (Ne), and combinations thereof.

The deposition methods disclosed herein include one or more steps of purging unwanted or unreacted material from a reactor using purge gases. The purge gas, which is used to purge away unconsumed reactants and/or reaction byproducts, is an inert gas that does not react with the precursors. Exemplary purge gases include, but are not limited to, argon (Ar), nitrogen (N₂), helium (He), neon (Ne), hydrogen (H₂), and combinations thereof. In certain embodiments, a purge gas such as Ar is supplied into the reactor at a flow rate ranging from about 10 to about 10000 sccm for about 0.1 to 1000 seconds, thereby purging the unreacted material and any byproduct that may remain in the reactor.

The respective steps of supplying the precursors, oxygen source, the ammonia-containing source, and/or other precursors, source gases, and/or reagents may be performed by changing the time for supplying them to change the stoichiometric composition of the resulting film.

In certain embodiments, the temperature of the reactor in the introducing step is at one or more temperatures ranging from about room temperature (e.g., 20° C.) to about 600° C. Alternative ranges for the substrate temperature have one or more of the following end points: 20, 25, 50, 75, 100, 125, 150, 175, 200, 225, 250, 275, 300, 325, 350, 375, 400, 425, 450, 475, and 500° C. Exemplary preferred temperature ranges include the following: 300 to 450° C., 350 to 450° C.

In yet another embodiment, a vessel for depositing a silicon-containing film includes one or more silicon precursor compounds described herein. In one particular embodiment, the vessel is at least one pressurizable vessel (preferably of stainless steel having a design such as disclosed in U.S. Pat. Nos. 7,334,595; 6,077,356; 5,069,244; and 5,465,766 the disclosure of which is hereby incorporated by reference. The container can comprise either glass (borosilicate or quartz glass) or type 316, 316L, 304 or 304L stainless steel alloys (UNS designation S31600, S31603, S30400 S30403) fitted with the proper valves and fittings to allow the delivery of one or more precursors to the reactor for a CVD or an ALD process. In this or other embodiments, the halogenated silanes and the primary amino-containing silicon compounds are provided in a pressurizable vessel comprised of stainless steel and the purity of the precursor is 98% by weight or greater or 99.5% or greater which is suitable for the semiconductor applications. The silicon precursor compounds are preferably substantially free of metal ions such as, Al³⁺ ions, Fe³⁺, Fe³⁺, Ni²⁺, Cr³⁺. As used herein, the term “substantially free” as it relates to Al³⁺ ions, Fe²⁺, Fe³⁺, Ni²⁺, Cr³⁺ means less than about 5 ppm (by weight), preferably less than about 3 ppm, and more preferably less than about 1 ppm, and most preferably about 0.1 ppm. In certain embodiments, such vessels can also have means for mixing the precursors with one or more additional precursor if desired. In these or other embodiments, the contents of the vessel(s) can be premixed with an additional precursor. Alternatively, the silicon precursor is and/or other precursor can be maintained in separate vessels or in a single vessel having separation means for maintaining the silicon precursor is and other precursor separate during storage.

Energy may be applied to at least one of the precursor, ammonia-containing source, reducing agent such as hydrogen plasma, other precursors or combination thereof to induce reaction and to form the film or coating on the substrate. Such energy can be provided by, but not limited to, thermal, plasma, pulsed plasma, helicon plasma, high density plasma, inductively coupled plasma, X-ray, e-beam, photon, remote plasma methods, and combinations thereof.

In certain embodiments, a secondary RF frequency source may be used to modify the plasma characteristics at the substrate surface. In embodiments wherein the deposition involves plasma, the plasma-generated process may comprise a direct plasma-generated process in which plasma is directly generated in the reactor, or alternatively a remote plasma-generated process in which plasma is generated outside of the reactor and supplied into the reactor.

The silicon precursors and/or other silicon-containing precursors may be delivered to the reaction chamber, such as a CVD or ALD reactor, in a variety of ways. In one embodiment, a liquid delivery system may be utilized. In an alternative embodiment, a combined liquid delivery and flash vaporization process unit may be employed, such as, for example, the turbo vaporizer manufactured by MSP Corporation of Shoreview, MN, to enable low volatility materials to be volumetrically delivered, which leads to reproducible transport and deposition without thermal decomposition of the precursor. In liquid delivery formulations, the precursors described herein may be delivered in neat liquid form, or alternatively, may be employed in solvent formulations or compositions comprising same. Thus, in certain embodiments the precursor formulations may include solvent component(s) of suitable character as may be desirable and advantageous in a given end use application to form a film on a substrate.

In this or other embodiments, it is understood that the steps of the methods described herein may be performed in a variety of orders, may be performed sequentially or concurrently (e.g., during at least a portion of another step), and any combination thereof. The respective step of supplying the precursors and the nitrogen-containing source gases may be performed by varying the duration of the time for supplying them to change the stoichiometric composition of the resulting silicon-containing film.

In a still further embodiment of the methods described herein, the film or the as-deposited film is subjected to a treatment step. The treatment step can be conducted during at least a portion of the deposition step, after the deposition step, and combinations thereof. Exemplary treatment steps include, without limitation, treatment via high temperature thermal annealing; plasma treatment; ultraviolet (UV) light treatment; laser; electron beam treatment and combinations thereof to affect one or more properties of the film. The films deposited with the silicon precursors described herein, when compared to films deposited with previously disclosed silicon precursors under the same conditions, have improved properties such as, without limitation, a wet etch rate that is lower than the wet etch rate of the film before the treatment step or a density that is higher than the density prior to the treatment step. In one particular embodiment, during the deposition process, as-deposited films are intermittently treated. These intermittent or mid-deposition treatments can be performed, for example, after each ALD cycle, after a certain number of ALD, such as, without limitation, one (1) ALD cycle, two (2) ALD cycles, five (5) ALD cycles, or after every ten (10) or more ALD cycles.

In an embodiment wherein the film is treated to UV treatment, film is exposed to broad band UV or, alternatively, an UV source having a wavelength ranging from about 150 nanometers (nm) to about 400 nm. In one particular embodiment, the as-deposited film is exposed to UV in a different chamber than the deposition chamber after a desired film thickness is reached.

In an embodiment where in the film is treated with a plasma, passivation layer such as carbon-doped silicon oxide is deposited to prevent chlorine and nitrogen contamination from penetrating film in the subsequent plasma treatment. The passivation layer can be deposited using atomic layer deposition or cyclic chemical vapor deposition.

In an embodiment wherein the film is treated with a plasma, the plasma source is selected from the group consisting of hydrogen plasma, plasma comprising hydrogen and helium, plasma comprising hydrogen and argon. Hydrogen plasma lowers film dielectric constant and boost the damage resistance to following plasma ashing process while still keeping the carbon content in the bulk almost unchanged.

The following examples illustrate certain aspects of the instant invention and do not limit the scope of the appended claims.

### EXAMPLES

In the following examples, unless stated otherwise, properties will be obtained from sample films that are deposited onto silicon wafer with resistivity of 5-20 Ω-cm as substrate.

In typical process conditions, unless stated otherwise, the chamber pressure is fixed at a pressure ranging from about 1 to about 5 Torr. Additional inert gas is used to maintain chamber pressure.

The film deposition steps are for plasma enhanced ALD. Unless otherwise specified, a total of 100 or 200 or 300 or 500 deposition cycles were used to get the desired film thickness.

### Comparative Example 1

A silicon nitride film was deposited using SiCl₄ and ammonia plasma in PEALD mode at 350° C. The ALD steps, listed on Table 1a, are as follows.

TABLE 1a
ALD steps used in PEALD deposition of silicon
nitride using SiCl₄ followed by ammonia plasma

| Step | Descriptions | Process parameters |
|---|---|---|
| 1. | Insert silicon wafer into a | |
| | PEALD reactor and heat to | |
| | desired temperature (350° C.) | |
| 2. | Expose silicon wafer with | SiCl₄ exposure = ~10.5 torr. |
| | silicon precursor | T = 350° C. |
| | | time = 2 seconds |
| 3. | Purge | Ar flow = 500 sccm |
| | | time = 20 seconds |
| 4. | Plasma stabilization step | Ar flow = 200 sccm |
| | | Plasma power = 1500 Watt |
| | | Plasma frequency = 2 MHz |
| | | time = 5 seconds |
| 5. | Plasma on | Ar flow = 100 sccm |
| | | NH₃ flow = 300 sccm |
| | | Plasma power = 1500 Watt |
| | | Plasma frequency = 2 MHz |
| | | time = 30 seconds |
| 6. | Purge | Ar flow = 500 sccm |
| | | time = 15 seconds |
| 7. | Remove Si wafer from the | |
| | reactor | |

Step 2-6 were repeated 300 times to get 101 Å of film. This translated to a growth per cycle (GPC) of 0.34 Å/cycle. The deposited film had an etch rate relative to the thermal silicon oxide reference in 0.5% dilute HF of >5.2. The etch rate relative to the thermal silicon oxide reference of a silicon nitride film is defined as the ratio of the etch rate of the silicon nitride to that of the thermal silicon oxide measured under the same conditions.

### Comparative Example 2

A silicon nitride film was deposited using tetrakis(n-propylamino)silane and ammonia plasma in an PEALD mode at 350° C., as described in Table 1b.

TABLE 1b
ALD steps used in PEALD deposition of silicon nitride using
tetrakis(n-propylamino)silane followed by ammonia plasma

| Step | Descriptions | Process parameters |
|---|---|---|
| 1. | Insert silicon wafer | |
| | into a PEALD reactor | |
| | and heat to desired | |
| | temperature (350° C.) | |
| 2. | Expose silicon wafer | Tetrakis(n- |
| | with silicon precursor | propylamino)silane |
| | | exposure ~15 torr |
| | | T = 350° C. |
| | | time = 2 seconds |
| 3. | Purge | Ar flow = 500 sccm |
| | | time = 20 seconds |
| 4. | Plasma stabilization | Ar flow = 200 sccm |
| | step | Plasma power = 1500 Watt |
| | | Plasma frequency = 2 MHz |
| | | time = 5 seconds |
| 5. | Plasma on | Ar flow = 100 sccm |
| | | NH₃ flow = 300 sccm |
| | | Plasma power = 1500 Watt |
| | | Plasma frequency = 2 MHz |
| | | time = 30 seconds |
| 6. | Purge | Ar flow = 500 sccm |
| | | time = 15 seconds |
| 7. | Remove Si wafer from | |
| | the reactor | |

The film thickness after 400 cycles was 65 Å which translated to a GPC of 0.16 Å/cycle. The deposited film bad an each rate relative to the thermal silicon oxide reference in 0.5% dilute HF of >3.1.

### Comparative Example 3

A silicon nitride film was deposited using tetrakis(n-propylamino)silane and SiCl₄ without any plasma at 350° C. as described in Table 1c.

TABLE 1c
ALD steps used in PEALD deposition of silicon
nitride using tetrakis(n-propylamino)silane

| Step | Descriptions | Process parameters |
|---|---|---|
| 1. | Insert silicon wafer into a | |
| | PEALD reactor and heat to | |
| | desired temperature (350° C.) | |
| 2. | Expose silicon wafer with | SiCl₄ exposure = ~10.5 torr |
| | halogenated silicon precursor | T = 350° C., time = 2 seconds |
| 3. | Purge | Ar flow = 500 sccm |
| | | time = 20 seconds |
| 4. | Expose silicon wafer with | Tetrakis(n-propylamino)silane |
| | primary aminosilane | exposure = ~15 torr · s |
| 5. | Purge | Ar flow = 500 sccm |
| | | time = 15 seconds |
| 6. | Remove Si wafer from the | |
| | reactor | |

Step 2-5 were repeated for 400 cycles. The deposited film was 20 Å, translating to <0.1 Å/cycle.

### Working Example 1

A silicon nitride film was deposited using a combination of halogenated silicon precursor and primary amino-containing silicon compound followed by ammonia plasma at 350° C.
Tetrachlorosilane (SiCl₄) was selected as halogenated silicon precursor example while tetrakis(n-propylamino)silane was selected as primary amino-containing silicon compound. The SiCl₄ was delivered at room temperature while tetrakis(n-propylamino) silane was delivered at 125° C. cannister temperature. The deposition process was performed using a 300 mm tool equipped with a remote plasma (2 MHz). The film thickness and refractive index were measured using ellipsometer. The film quality was characterized by its etch rate relative to the thermal silicon oxide reference, defined as the ratio of the film's etch rate to that of the thermal silicon oxide measured under the same conditions, using 0.5% dilute hydrofluoric acid (HF)/H₂O at room temperature.
The ALD steps, shown in Table 2, are as follows:

TABLE 2
ALD steps using SiCl₄ and tetrakis(n-propylamino)silane
followed by ammonia plasma

| Step | Descriptions | Process parameters |
|---|---|---|
| 1. | Insert silicon wafer into a | |
| | PEALD reactor and heat to | |
| | desired temperature (350° C.) | |
| 2. | Expose silicon wafer with | SiCl₄ exposure = ~10.5 torr |
| | halogenated silicon precursor | T = 350° C., time = 2 seconds |
| 3. | Purge | Ar flow = 500 sccm |
| | | time = 20 seconds |
| 4. | Expose silicon wafer with | Tetrakis(n-propylamino)silane |
| | primary amino-silane | exposure = ~15 torr, time = 10 |
| | | seconds |
| 5. | Purge | Ar flow = 500 sccm |
| | | time = 20 seconds |
| 6. | Plasma stabilization step | Ar flow = 200 sccm |
| | | Plasma power = 1500 Watt |
| | | Plasma frequency = 2 MHz |
| | | time = 5 seconds |
| 7. | Plasma on | Ar flow = 100 sccm |
| | | NH₃ flow = 100 sccm |
| | | Plasma power = 1500 Watt |
| | | Plasma frequency = 2 MHz |
| | | time = 30 seconds |
| 8. | Purge | Ar flow = 500 sccm |
| | | time = 15 seconds |
| 9. | Remove Si wafer from the | |
| | reactor | |

Steps 2-8 were repeated 400 times to deposit 180 Å of films. This translated to a GPC of 0.45 Å/cycle. The as-deposited film exhibits higher 0.5% dilute HF etch rate resistance. The etch rate of the deposited film relative to the thermal silicon oxide reference in 0.5% dilute HF was 1.3, demonstrating much better etch resistance compared to typical ALD processes as shown in comparable examples with just one silicon precursor under similar deposition conditions.

### Working Example 2

A silicon nitride film was deposited using a combination of halogenated silicon precursor and primary amino-containing silicon compound followed by a hydrogen plasma at 350° C. Tetrachlorosilane (SiCl₄) was selected as a halogenated silicon precursor example while tetrakis(n-propylamino)silane was selected as primary amino-containing silicon compound. The ALD steps, shown in Table 3, are as follows:

TABLE 3
ALD steps using SiCl₄ and tetrakis(n-propylamino)silane
followed by hydrogen plasma

| Step | Descriptions | Process parameters |
|---|---|---|
| 1. | Insert silicon wafer into a | |
| | PEALD reactor and heat to | |
| | desired temperature (350° C.) | |
| 2. | Expose silicon wafer with | SiCl₄ exposure = ~10.5 torr · s |
| | halogenated silicon precursor | T = 350° C., time = 2 seconds |
| 3. | Purge | Ar flow = 500 sccm |
| | | time = 20 seconds |
| 4. | Expose silicon wafer with | Tetrakis(n-propylamino)silane |
| | aminosilane | exposure = ~15 torr · s, 10 s |
| 5. | Purge | Ar flow = 500 sccm |
| | | time = 30 seconds |
| 6. | Plasma stabilization step | Ar flow = 200 sccm |
| | | Plasma power = 1500 Watt |
| | | Plasma frequency = 2 MHz |
| | | time = 0.1 seconds |
| 7. | Plasma on | Ar flow = 100 sccm |
| | | H₂ flow = 300 sccm |
| | | Plasma power = 1500 Watt |
| | | Plasma frequency = 2 MHz |
| | | time = 30 seconds |
| 8. | Purge | Ar flow = 500 sccm |
| | | time = 15 seconds |
| 9. | Remove Si wafer from the | |
| | reactor | |

Steps 2-8 were repeated 200 times to deposit 40 Å of films. This translated to PEALD a growth rate of 0.20 Å/cycle. The film exhibited higher 0.5% dilute HF etch rate resistance. The etch rate of the deposited film relative to the thermal silicon oxide reference was 0.14, demonstrating excellent etch resistance compared to typical ALD processes as shown in comparable examples with just one silicon precursor under similar deposition conditions.

Although illustrated and described above with reference to certain specific embodiments and working examples, the present invention is nevertheless not intended to be limited to the details shown. Rather, various modifications may be made in the details within the scope and range of equivalents of the claims and without departing from the spirit of the invention. It is expressly intended, for example, that all ranges broadly recited in this document include within their scope all narrower ranges which fall within the broader ranges.

The following is claimed:

1. A method for deposition of silicon and nitrogen containing dielectric film via an atomic layer deposition (ALD) process, comprising:
a) providing at least one substrate into a reactor at a temperature ranging from about 25° C. to about 600° C. and optionally maintaining the reactor at a pressure of about 100 torr or less;
b) introducing into the reactor at least a first silicon precursor comprising at least two halogen atoms to form a silicon-containing layer;
c) purging any unreacted precursor from the reactor using inert gas;
d) introducing into the reactor at least a second silicon precursor, comprising at least two primary amino moieties, which reacts with the silicon-containing layer to form a film comprising silicon and nitrogen;
e) purging the reactor using inert gas;
f) introducing a plasma source into the reactor to react with the film comprising silicon and nitrogen;
g) purging any reaction by-products from the reactor using inert gas, and
h) repeating steps b to g to bring the film comprising silicon and nitrogen to a desired thickness.

2. The method according to claim 1 wherein the first silicon precursor comprising at least two halogen atoms is at least one selected from the group consisting of: i) halogenated silanes, ii) halogenated siloxanes, iii) halogenated silazanes, and iv) halogenated carbosilanes.

3. The method according to claim 1 wherein the first silicon precursor comprising at least two halogen atoms is selected from the group consisting of trichlorosilane, tetrachlorosilane, hexachlorodisilane, pentachlorodisilane, tetrachlorodisilane, octachlorotrisilane, and dichlorosilane.

4. The method according to claim 1 wherein the first silicon precursor comprising at least two halogen atoms is a halogenated siloxane selected from the group consisting of hexachlorodisiloxane, pentachlorodisiloxane, tetrachlorodisiloxane, and octaclorotrisiloxane.

5. The method according to claim 1 wherein the first silicon precursor comprising at least two halogen atoms is a halogenated silazane selected from the groups represented by the following Formula I: 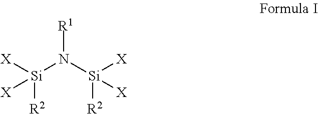
wherein R¹ is selected from the group consisting of hydrogen, a linear or branched C₁ to C₁₀ alkyl group, a linear or branched C₂ to C₁₀ alkenyl group, a linear or branched C₂ to C₁₀ alkynyl group, a C₃ to C₁₀ cyclic alkyl group, a C₂ to C₆ dialkylamino group, an electron withdrawing group, and a C₆ to C₁₀ aryl group; R² is selected from the group consisting of hydrogen, a linear or branched C₁ to C₁₀ alkyl group, a linear or branched C₂ to C₆ alkenyl group, a linear or branched C₃ to C₆ alkynyl group, a C₃ to C₁₀ cyclic alkyl group, a C₂ to C₆ dialkylamino group, a C₆ to C₁₀ aryl group, a linear or branched C₁ to C₆ fluorinated alkyl group, an electron withdrawing group, and a halide selected from the group consisting of Cl, Br, and I; and X is a halide selected from the group consisting of Cl, Br, and I.

6. The method according to claim 1, wherein the second silicon precursor primary amino-containing silicon compound is selected from the group consisting of compounds represented by the following Formula II below: 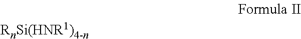
wherein R is selected from the group consisting of hydrogen, a linear or branched C₁ to C₁₀ alkyl group, a linear or branched C₂ to C₁₀ alkenyl group, a linear or branched C₂ to C₁₀ alkynyl group, a C₃ to C₁₀ cyclic alkyl group, a C₂ to C₆ dialkylamino group, an electron withdrawing group, and a C₆ to C₁₀ aryl group; R¹ is selected from the group consisting of hydrogen, a linear or branched C₁ to C₁₀ alkyl group, a linear or branched C₂ to C₆ alkenyl group, a linear or branched C₃ to C₆ alkynyl group, a C₃ to C₁₀ cyclic alkyl group, a C₂ to C₆ dialkylamino group, a C₆ to C₁₀ aryl group, a linear or branched C₁ to C₆ fluorinated alkyl group, an electron withdrawing group, and a halide selected from the group consisting of Cl, Br, and I; and n=0, 1, and 2.

7. The method according to claim 6, wherein the second silicon precursor primary amino-containing silicon compound is one or both of Si(HNEt)₄, and Si(HNPr-n)₄

8. The method according to claim 1, wherein the second silicon precursor, comprising at least two primary amino moieties, is selected from the group consisting of compounds according to Formula III below: 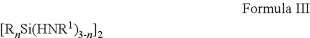
wherein R is selected from the group consisting of hydrogen, a linear or branched C₁ to C₁₀ alkyl group, a linear or branched C₂ to C₁₀ alkenyl group, a linear or branched C₂ to C₁₀ alkynyl group, a C₃ to C₁₀ cyclic alkyl group, a C₂ to C₆ dialkylamino group, an electron withdrawing group, and a C₆ to C₁₀ aryl group; R¹ is selected from the group consisting of hydrogen, a linear or branched C₁ to C₁₀ alkyl group, a linear or branched C₂ to C₆ alkenyl group, a linear or branched C₂ to C₆ alkynyl group, a C₃ to C₁₀ cyclic alkyl group, a C₂ to C₆ dialkylamino group, a C₆ to C₁₀ aryl group, a linear or branched C₁ to C₆ fluorinated alkyl group, an electron withdrawing group, and a halide selected from the group consisting of Cl, Br, and I; and n=0, 1, and 2.

9. The method according to claim 8 wherein the silicon precursor, comprising at least two primary amino moieties is selected from the group consisting of Si₂(HNEt)₆, Me(EtNH)₂SiSi(HNEt)₂Me, Me₂(EtNH)SiSi(HNEt)Me₂, Si₂(HNMe)₆, Me(MeNH)₂SiSi(HNMe)₂Me, and Me₂(MeNHe)SiSi(HNMe)Me₂.

10. A method for deposition of silicon and nitrogen containing dielectric film via an atomic layer deposition (ALD) process, comprising:
a) providing at least one substrate into a reactor at a temperature ranging from about 25° C. to about 600° C. and optionally maintaining the reactor at a pressure of about 100 torr or less;
b) introducing at least a first silicon precursor comprising at least two primary amino moieties to form a film comprising a silicon containing layer;
c) purging any unreacted precursor from the reactor using inert gas;
d) introducing into the reactor at least a second silicon precursor comprising at least two halogen atoms to react with the silicon containing layer to form a film comprising silicon and nitrogen;
e) purging the reactor using inert gas;
f) introducing a plasma source into the reactor to react with the film comprising silicon and nitrogen;
g) purging any reaction by-products from the reactor using inert gas, and
h) repeating steps b to g to bring the film comprising silicon and nitrogen to a desired thickness.

11. The method according to claim 10 wherein the second silicon precursor comprising at least two halogen atoms is at least one selected from the group consisting of: i) halogenated silanes, ii) halogenated siloxanes, iii) halogenated silazanes, and iv) halogenated carbosilanes.

12. The method according to claim 10 wherein the second silicon precursor comprising at least two halogen atoms is selected from the group consisting of trichlorosilane, tetrachlorosilane, hexachlorodisilane, pentachlorodisilane, tetrachlorodisilane, octachlorotrisilane, and dichlorosilane.

13. The method according to claim 10 wherein the second silicon precursor comprising at least two halogen atoms is a halogenated siloxane selected from the group consisting of hexachlorodisiloxane, pentachlorodisiloxane, tetrachlorodisiloxane, and octaclorotrisiloxane.

14. The method according to claim 10 wherein the second silicon precursor comprising at least two halogen atoms is a halogenated silazane selected from the groups represented by the following Formula I: 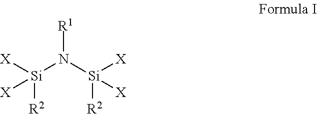
wherein R¹ is selected from the group consisting of hydrogen, a linear or branched C₁ to C₁₀ alkyl group, a linear or branched C₂ to C₁₀ alkenyl group, a linear or branched C₂ to C₁₀ alkynyl group, a C₃ to C₁₀ cyclic alkyl group, a C₂ to C₆ dialkylamino group, an electron withdrawing group, and a C₆ to C₁₀ aryl group; R² is selected from the group consisting of hydrogen, a linear or branched C₁ to C₁₀ alkyl group, a linear or branched C₂ to C₆ alkenyl group, a linear or branched C₃ to C₆ alkynyl group, a C₃ to C₁₀ cyclic alkyl group, a C₂ to C₆ dialkylamino group, a C₆ to C₁₀ aryl group, a linear or branched C₁ to C₆ fluorinated alkyl group, an electron withdrawing group, and a halide selected from the group consisting of Cl, Br, and I; and X is a halide selected from the group consisting of Cl, Br, and I.

15. The method according to claim 10, wherein the primary amino-containing silicon compound is selected from the group consisting of compounds represented by the following Formula II below: 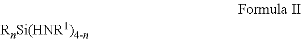
wherein R is selected from the group consisting of hydrogen, a linear or branched C₁ to C₁₀ alkyl group, a linear or branched C₂ to C₁₀ alkenyl group, a linear or branched C₂ to C₁₀ alkynyl group, a C₃ to C₁₀ cyclic alkyl group, a C₂ to C₆ dialkylamino group, an electron withdrawing group, and a C₆ to C₁₀ aryl group; R¹ is selected from the group consisting of hydrogen, a linear or branched C₁ to C₁₀ alkyl group, a linear or branched C₂ to C₆ alkenyl group, a linear or branched C₃ to C₆ alkynyl group, a C₃ to C₁₀ cyclic alkyl group, a C₂ to C₆ dialkylamino group, a C₆ to C₁₀ aryl group, a linear or branched C₁ to C₆ fluorinated alkyl group, an electron withdrawing group, and a halide selected from the group consisting of Cl, Br, and I; and n=0, 1, and 2.

16. The method according to claim 15, wherein the primary amino-containing silicon compound is one or both of Si(HNEt)₄, and Si(HNPr-n)₄

17. The method according to claim 10, wherein the first silicon precursor, comprising at least two primary amino moieties, is selected from the group consisting of compounds according to Formula III below: 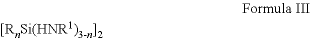
wherein R is selected from the group consisting of hydrogen, a linear or branched C₁ to C₁₀ alkyl group, a linear or branched C₂ to C₁₀ alkenyl group, a linear or branched C₂ to C₁₀ alkynyl group, a C₃ to C₁₀ cyclic alkyl group, a C₂ to C₆ dialkylamino group, an electron withdrawing group, and a C₆ to C₁₀ aryl group; R¹ is selected from the group consisting of hydrogen, a linear or branched C₁ to C₁₀ alkyl group, a linear or branched C₂ to C₆ alkenyl group, a linear or branched C₂ to C₆ alkynyl group, a C₃ to C₁₀ cyclic alkyl group, a C₂ to C₆ dialkylamino group, a C₆ to C₁₀ aryl group, a linear or branched C₁ to C₆ fluorinated alkyl group, an electron withdrawing group, and a halide selected from the group consisting of Cl, Br, and I; and n=0, 1, and 2.

18. The method according to claim 17 wherein the first silicon precursor, comprising at least two primary amino moieties, is selected from the group consisting of Si₂(HNEt)₆, Me(EtNH)₂SiSi(HNEt)₂Me, Me₂(EtNH)SiSi(HNEt)Me₂, Si₂(HNMe)₆, Me(MeNH)₂SiSi(HNMe)₂Me, and Me₂(MeNHe)SiSi(HNMe)Me₂.
